(19) United States
(12) Patent Application Publication
(10) Pub. No.: US 2026/0075946 A1
(43) Pub. Date: Mar. 12, 2026

(54) ARRAY SUBSTRATE AND DISPLAY DEVICE

(71) Applicant: Sharp Display Technology Corporation, Kameyama City (JP)

(72) Inventor: Masahito SANO, Kameyama City (JP)

(21) Appl. No.: 19/260,811

(22) Filed: Jul. 7, 2025

(30) Foreign Application Priority Data
Jul. 9, 2024 (JP) 2024-110168

(51) Int. Cl. H10D 86/40; G02F 1/1368; H10D 86/60

(52) U.S. Cl. CPC H10D 86/451; G02F 1/1368; H10D 86/60

(57) ABSTRACT

An array substrate includes a semiconductor section, a first insulation film in a layer upper than the semiconductor section, a first electrode in a layer upper than the first insulation film and overlapping the semiconductor section, a second insulation film in a layer upper than the first electrode, and a third insulation film in a layer upper than the second insulation film. The first electrode is made of transparent electrode material. The first insulation film is made of inorganic insulation material and includes a first contact hole in a portion overlapping the semiconductor section and the first electrode, and the semiconductor section and the first electrode are connected via the first contact hole. The third insulation film is made of organic insulation material. The second insulation film is made of inorganic insulation material and covers at least a first overlapping portion of the first electrode overlapping the first contact hole.

### CROSS REFERENCE TO RELATED APPLICATION

This application claims priority from Japanese Patent Application No. 2024-110168 filed on Jul. 9, 2024. The entire contents of the priority application are incorporated herein by reference.

### TECHNICAL FIELD

The present technology described herein relates to an array substrate and a display device in which impurities are less likely to spread to a semiconductor section.

### BACKGROUND

An organic light emitting display device has been known as an example of a display device. Such an organic light emitting display device includes an insulating layer disposed on a substrate (an array substrate), a resistance layer of oxide semiconductor disposed on the insulating layer, a wiring layer connected to both side portions of the resistance layer, an organic layer disposed on the upper portion including the resistance layer and the wiring layer, and a capping layer formed on the organic layer to overlap the resistance layer.

In a pixel area of the organic light emitting display device, a contact hole is formed in the insulating layer that is disposed between the active layer made of oxide semiconductor material and the source/drain electrode. The active layer and the source/drain electrode are connected via the contact hole. With the source/drain electrode being made of transparent electrode material, light transmittance of the pixel area is improved. However, the transparent electrode material is likely to transmit impurities such as moisture that are contained in an organic layer disposed in a layer upper than a layer of the source/drain electrode. Therefore, after the organic light emitting display device is produced, impurities pass through the source/drain electrode and spread to the active layer. This may change the characteristics of thin film transistors that include the active layers.

### SUMMARY

The technology described herein was made in view of the above circumstances. An object is to suppress spread of impurities to a semiconductor section.
(1) An array substrate according to the technology described herein includes a semiconductor section made of semiconductor material, a first insulation film disposed in a layer upper than the semiconductor section, a first electrode that is disposed in a layer upper than the first insulation film and a portion of which overlaps a portion of the semiconductor section, a second insulation film disposed in a layer upper than the first electrode, and a third insulation film disposed in a layer upper than the second insulation film. The first electrode is made of transparent electrode material. The first insulation film is made of inorganic insulation material and includes a first contact hole in a portion overlapping the semiconductor section and the first electrode, and the semiconductor section and the first electrode are connected via the first contact hole. The third insulation film is made of organic insulation material. The second insulation film is made of inorganic insulation material and covers at least a first overlapping portion of the first electrode that overlaps the first contact hole.
(2) The array substrate may further include, in addition to (1), a pixel electrode that is disposed in a layer upper than the third insulation film and a portion of which overlaps the first electrode. The third insulation film may include a second contact hole in a portion that overlaps the first electrode and the pixel electrode and does not overlap the first contact hole, and the first electrode and the pixel electrode may be connected via the second contact hole. The second insulation film may include a third contact hole that is communicated with the second contact hole and cover an entire area of the first electrode except for a second overlapping portion of the first electrode that overlaps the second contact hole.
(3) In the array substrate, in addition to (2), the second insulation film may include a first insulation portion that overlaps the first electrode and a second insulation portion that surrounds the first insulation portion.
(4) In the array substrate, in addition to (2) or (3), the pixel electrode may include an electrode overlapping section that overlaps the first electrode and an electrode non-overlapping section that does not overlap the first electrode and the second insulation film may not be disposed in an area overlapping the electrode non-overlapping section.
(5) In the array substrate, in addition to (2) or (3), the pixel electrode may include an electrode overlapping section that overlaps the first electrode and an electrode non-overlapping section that does not overlap the first electrode, and the second insulation film may be disposed in an area overlapping the electrode non-overlapping section.
(6) The array substrate may further include, in addition to (1), a pixel electrode that is disposed in a layer upper than the third insulation film and a portion of which overlaps the first electrode. The third insulation film may include a second contact hole in a portion that overlaps the first electrode and the pixel electrode and does not overlap the first contact hole, and the first electrode and the pixel electrode may be connected via the second contact hole. The second insulation film may be disposed in an area that overlaps the first overlapping portion and a surrounding portion of the first electrode that surrounds the first overlapping portion. The second insulation film may not be disposed in an area that overlaps a second overlapping portion of the first electrode that overlaps the second contact hole and an area that overlaps a surrounding portion of the first electrode that surrounds the second overlapping portion.
(7) The array substrate may further include, in addition to any one of (1) to (6), a pixel electrode that is disposed in a layer upper than the third insulation film and a portion of which overlaps the first electrode, and a first line made of conductive material: having light blocking properties and disposed in a layer lower than the first insulation film. The third insulation film may include a second contact hole in a portion that overlaps the first electrode and the pixel electrode and the first line, and the first electrode and the pixel electrode may be connected via the second contact hole.
(8) In the array substrate, in addition to any one of (1) to (7), the second insulation portion may include silicon nitride as the inorganic insulation material.
(9) The array substrate may further include, in addition to any one of (1) to (8), a fourth insulation film disposed in a layer lower than the semiconductor section, a second electrode disposed in a layer lower than the fourth insulation film and disposed to overlap a portion of the semiconductor section, and a third electrode disposed not to overlap the first electrode and the second electrode and connected to the semiconductor section. The first electrode, the second electrode, the third electrode, and the semiconductor section may be configured as a transistor.
(10) The array substrate may further include, in addition to any one of (1) to (8), a fifth insulation film disposed in a layer upper than the semiconductor section and lower than the first insulation film, a fourth electrode disposed in a layer upper than the fifth insulation film and lower than the first insulation film and disposed to overlap a portion of the semiconductor section, and a third electrode disposed not to overlap the first electrode and the fourth electrode and connected to the semiconductor section. The first electrode, the fourth electrode, the third electrode, and the semiconductor section may be configured as a transistor.
(11) A display device according to the technology described herein includes the array substrate of any one of (1) to (10) and an opposed substrate disposed to opposite the array substrate.

According to the technology described herein, impurities are less likely to spread to a semiconductor section.

### BRIEF DESCRIPTION OF THE DRAWINGS

FIG. 1 is a general perspective view illustrating a head-mounted display that is mounted on a head of a user according to a first embodiment.

FIG. 2 is a general side view illustrating an optical relation of a liquid crystal display device and a lens that are included in a head mounting device of the head-mounted display according to the first embodiment and an eyeball of the user.

FIG. 3 is a plan view illustrating a liquid crystal panel and a flexible substrate included in the liquid crystal display device according to the first embodiment.

FIG. 4 is a cross-sectional view of the liquid crystal panel according to the first embodiment.

FIG. 5 is a plan view illustrating a pixel arrangement in the display area of the array substrate included in the liquid crystal panel according to the first embodiment.

FIG. 6 is an enlarged plan view of a portion of the array substrate near r a TFT according to the first embodiment.

FIG. 7 is a cross-sectional view of the array substrate according to the first embodiment taken along line vii-vii in FIG. 5.

FIG. 8 is a cross-sectional view of the array substrate according to the first embodiment taken along line viii-viii in FIG. 6.

FIG. 9 is a cross-sectional view of the array substrate according to the first embodiment taken along line ix-ix in FIG. 6.

FIG. 10 is a cross-sectional view of an array substrate according to a second embodiment corresponding to a portion taken along a same line in FIG. 7.

FIG. 11 is a cross-sectional view of the array substrate according to the second embodiment corresponding to a portion taken along a same line in FIG. 8.

FIG. 12 is a cross-sectional view of the array substrate according to the second embodiment corresponding to a portion taken along a same line in FIG. 9.

FIG. 13 is an enlarged plan view of a portion of an array substrate near a TFT according to a third embodiment.

FIG. 14 is a cross-sectional view of the array substrate according to the third embodiment taken along line xiv-xiv in FIG. 13.

### DETAILED DESCRIPTION

### First Embodiment

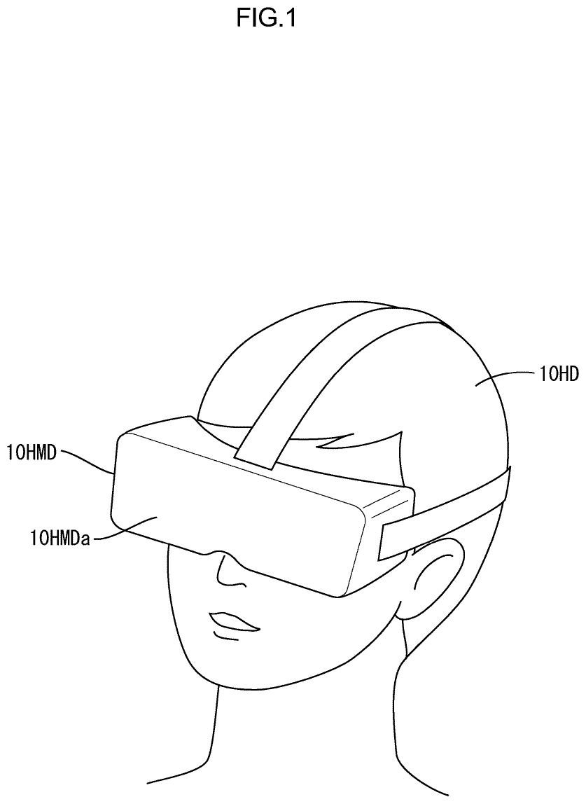

A first embodiment will be described with reference to FIGS. 1 to 9. In this embodiment section, a goggle-type head-mounted display (HMD) 10HMD and a liquid crystal display device 10 (a display device) used therein will be described as an example. X-axis, Y-axis and Z-axis may be present in the drawings and each of the axial directions represents a direction represented in each drawing.

An outer appearance of the goggle-type head-mounted display 10HMD will be described with reference to FIG. 1. As illustrated in FIG. 1, the goggle-type head-mounted display 10HMD includes a head mounting device 10HMDa that is mounted on the head 10HD of the user. The head mounting device 10HMDa covers both eyes of the user.

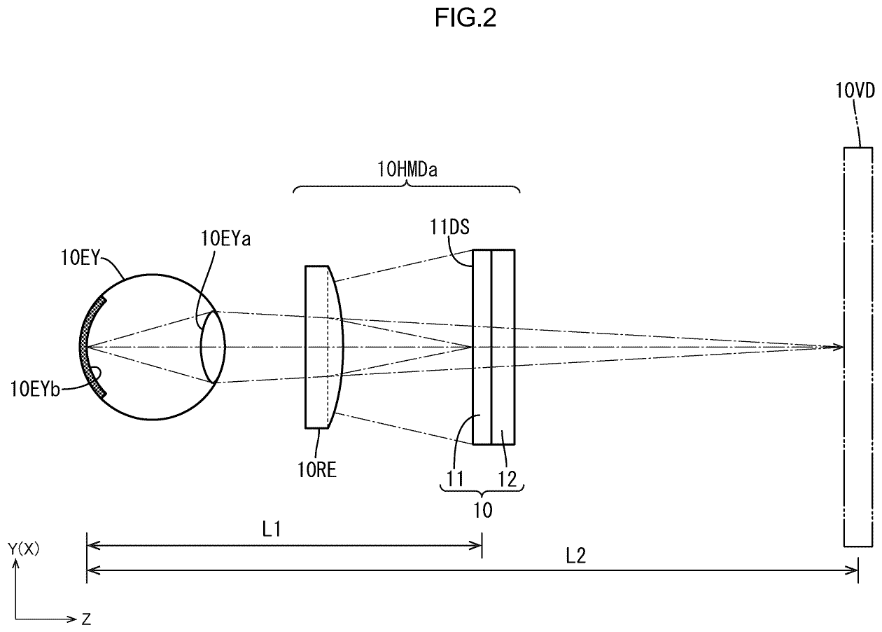

A configuration of the head mounting device 10HMDa will be described with reference to FIG. 2. As illustrated in FIG. 2, the head mounting device 10HMDa at least includes the liquid crystal display device 10 displaying images thereon and a lens 10RE with which the images displayed on the liquid crystal display device 10 are formed (imaging) on the eyeballs EY of the user. The liquid crystal display device 10 at least includes a liquid crystal panel 11 (a display device) and a backlight 12 (a lighting device) that supplies light to the liquid crystal panel 11. The liquid crystal panel 11 includes a plate surface that is opposed to the lens 10RE as a display surface 11DS on which images are displayed. The lens 10RE is disposed between the liquid crystal display device 10 and the eyeballs 10EY of the user and makes the light rays transmitting therethrough to be refracted. By adjusting a focal distance of the lens 10RE, images formed on the retina (eye) 10EYb through the crystalline lens 10EYa of the eyeball 10EY can be seen by a user as if the images are displayed on a virtual display 10VD that is present in appearance at a position away from the eyeball 10EY by a distance L2. The distance L2 is much greater than an actual distance L1 from the eyeball 10EY to the liquid crystal display device 10. Accordingly, the user sees a magnified image (a virtual image) displayed on the virtual display 10VD having a screen size (for example, from dozens of inches to several hundred inches) much greater than the screen size (for example, from several numbers of 0.1 inches to several inches) of the liquid crystal display device 10.

One liquid crystal display device 10 may be mounted in the head mounting device 10HMDa and images for a right eye and images for a left eye may be displayed on the liquid crystal display device 10. Two liquid crystal display devices 10 may be mounted in the head mounting device 10HMDa and images for a right eye may be displayed on one of the two liquid crystal display devices 10 and images for a left eye may be displayed on the other one of the two liquid crystal display devices 10. The head mounting device 10HMDa may include earphone that is put on user's ears and through which sounds are output.

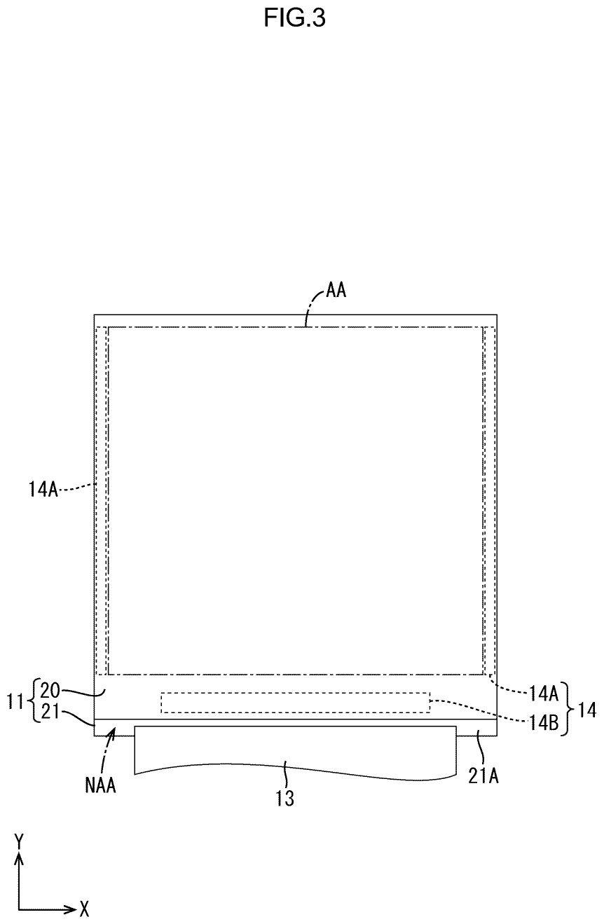

A configuration of the liquid crystal panel 11 included in the liquid crystal display device 10 will be described with reference to FIG. 3. The backlight 12 has a known configuration and includes a light source such as LEDS and optical members for converting the light from the light source into planar light by adding optical effects to the light from the light source. As illustrated in FIG. 3, the liquid crystal panel 11 has a rectangular plan view shape as a whole. A middle section of a screen of the liquid crystal panel 11 is configured as a display area AA in which images are displayed. An outer section in a frame shape surrounding the display area AA in the screen of the liquid crystal panel 11 is configured as a non-display area NAA in which images are not displayed. In FIG. 3, an area defined by a chain line is the display area AA. The liquid crystal panel 11 of this embodiment, which is used for the head-mounted display 10HMD, has quite high precision and the pixel density is about 1000 ppi or higher. As illustrated in FIG. 3, the liquid crystal panel 11 includes a pair of substrates 20, 21 that are bonded to each other. One of the substrates 20, 21 on the front side is an opposed substrate 20 (a second substrate, a CF substrate) and another one on the back side is an array substrate 21 (a first substrate, an active matrix substrate). The opposed substrate 20 and the array substrate 21 include substantially transparent glass substrates 20GS, 21GS having high light transmissive properties and various films formed in layers on inner sides of the glass substrates 20GS, 21GS. The glass substrate 20GS, 21Gs includes alkali-free glass as main material. The array substrate 21 is larger than the opposed substrate 20. A projecting portion 21A, which is an edge portion of the array substrate 21, projects from a corresponding edge of the opposed substrate 20. A flexible board 13 is mounted on the projecting portion 21A of the array substrate 21. The flexible board 13 includes a substrate having insulating properties and flexibility and multiple traces formed on the substrate. One edge of the flexible board 13 is connected to the array substrate 21 and other edge of the flexible board 13 is connected to an external control board (a signal supply). Various kinds of signals supplied from the control board are transferred to the liquid crystal panel 11 via the flexible board 13.

As illustrated in FIG. 3, a circuit 14 (a surrounding circuit) is mounted on the non-display area NAA of the liquid crystal panel 11. The circuit 14 includes a pair of first circuits 14A and a second circuit 14B. The pair of first circuits 14A are disposed to sandwich the display area AA with respect to the X-axis direction. The first circuit 14A is disposed in a belt-shaped area extending along the Y-axis direction. The first circuits 14A are for supplying scan signals to gate lines 25, 29, which will be described later, and are monolithically fabricated on the array substrate 21. The first circuit 14A is a gate driver monolithic (GDM) circuit. The scan signals include a potential higher than a threshold voltage of a TFT 27, which will be described later. The first circuit 14A includes a shift resistor circuit that is configured to output scan signals at predetermined timing and a buffer circuit that is configured to amplify scan signals. The second circuit 14B is disposed in an area between the display area AA and the flexible board 13 with respect to the Y-axis direction. The second circuit 14B is disposed in a belt-shaped area extending along the X-axis direction. The second circuit 14B is for supplying image signals (data signals) to source lines 26, which will be described later, and is monolithically fabricated on the array substrate 21. The second circuit 14B includes a source shared driving (SSD) circuit. The second circuit 14B is configured as a switching component that distributes the image signals supplied from the flexible board 13 to the source lines 26. The second circuit 14B may be disposed to overlap the opposed substrate 20 similar to the first circuit 14A.

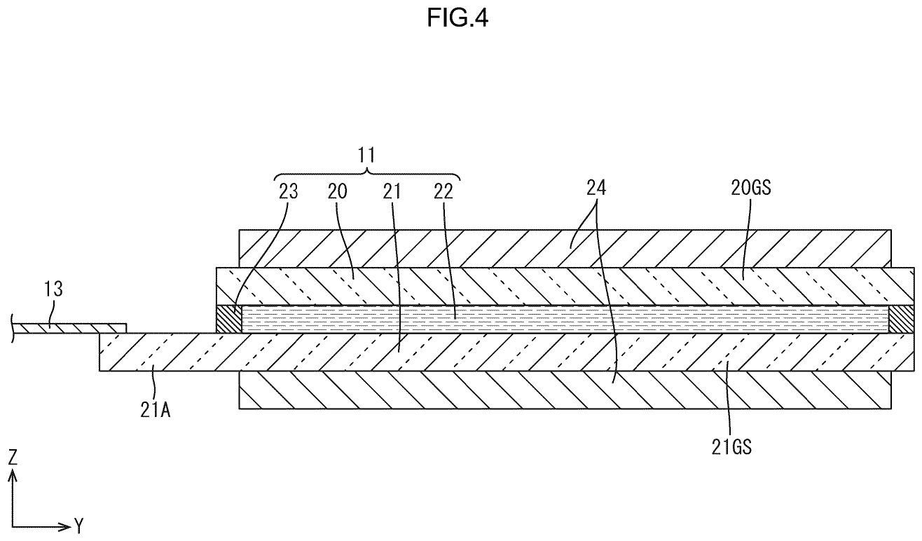

Next, a cross-sectional configuration of the liquid crystal panel 11 will be described with reference to FIG. 4. As illustrated in FIG. 4, the substrates 20, 21 are disposed opposite each other with having a space therebetween with respect to the Z-axis direction that is a normal direction to main surfaces of the substrates 20, 21. At least a liquid crystal layer 22 and a sealing portion 23 that seals the liquid crystal layer 22 are disposed between the substrates 20, 21. The liquid crystal layer 22 includes liquid crystal molecules that are substances having optical characteristics that change according to application of an electric field. The sealing portion 23 has a rectangular frame plan view shape (endless loop shape) as a whole and surrounds the entire periphery of the liquid crystal layer 22 in the non-display area NAA. The sealing portion 23 keeps the gap (a cell gap) corresponding to the thickness of the liquid crystal layer 22. Polarizing plates 24 are bonded to outer surfaces of the substrates 20, 21, respectively.

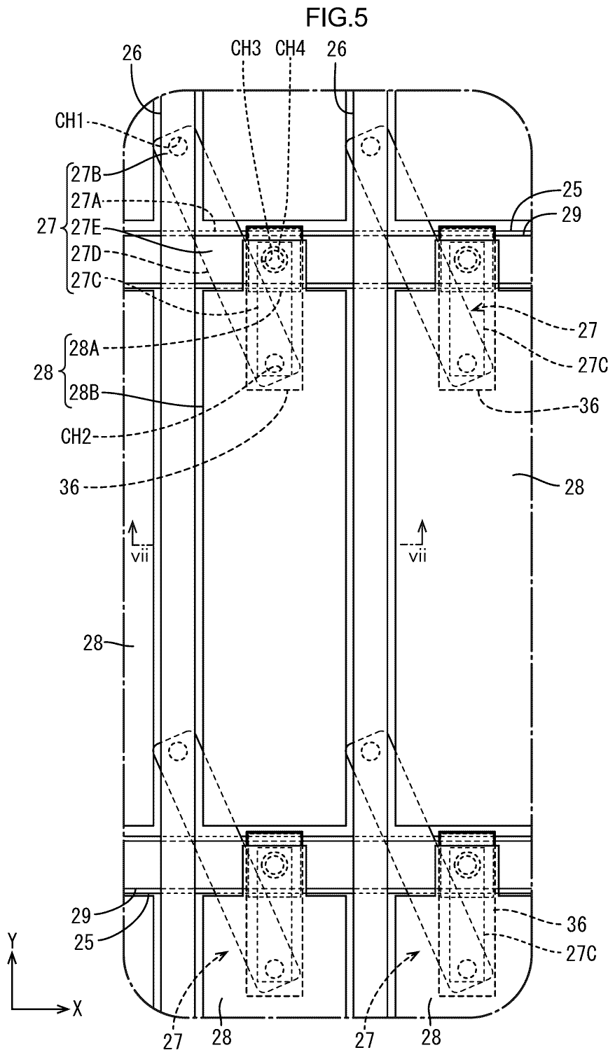

Pixel arrangement in the display area AA of the array substrate 21 will be described with reference to FIG. 5. As illustrated in FIG. 5, lower layer gate lines 25 (a first line, a lower layer scanning line, a first scanning line), upper layer gate lines 29 (an upper layer scanning line, a second scanning line), and source lines 26 (an image line, a signal line) are disposed in the display area AA of an inner surface of the array substrate 21. The lower layer gate lines 25 and the upper layer gate lines 29 extend along the X-axis direction (a first direction) and cross the display area AA laterally and overlap with each other. The upper layer gate line 29 is narrower than the lower layer gate line 25. The lower layer gate line 25 and the upper layer gate line 29 may be disposed such that center lines thereof with respect to the width direction (the Y-axis direction) match or may be disposed such that the center lines do not match. The lower layer gate lines 25 and the upper layer gate lines 29 are arranged at intervals with respect to the Y-axis direction. The lower layer gate lines 25 and the upper layer gate lines 29 are supplied with the scan signals that are output from the first circuit 14A. The lower layer gate line 25 and the upper layer gate line 29 that are overlapped with each other are supplied with scan signals at a same timing from the first circuit 14A and always have a same potential. The source lines 26 extend along the Y-axis direction (a second direction crossing the first direction) and cross the display area AA vertically. The source lines 26 cross the lower layer gate lines 25 and the upper layer gate lines 29. The source lines 26 are arranged at intervals in the X-axis direction. The lower layer gate lines 25 and the upper layer gate lines 29 and the source lines 26 are arranged in a grid in a plan view. The image signals output from the second circuit 14B are supplied to the source lines 26.

As illustrated in FIG. 5, TFTs 27 (transistors, switching components) and pixel electrodes 28 are arranged near the crossing portions where the gate lines 25, 29 and the source lines 26 cross. The TFTs 27 and the pixel electrodes 28 are arranged regularly along the X-axis direction and the Y-axis direction. The TFTs 27 at least include lower layer gate electrodes 27A (a second electrode), source electrodes 27B (a third electrode), drain electrodes 27C (a first electrode), semiconductor sections 27D, and upper layer gate electrodes 27E (a fourth electrode). The lower layer gate electrode 27A is a portion of the lower layer gate line 25. The upper layer gate electrode 27E is a portion of the upper layer gate line 29. The source electrode 27B is a portion of the source line 26. The drain electrode 27C is disposed away from the source electrode 27B and connected to the pixel electrode 28. The semiconductor section 27D is connected to the source electrode 27B and the drain electrode 27C. The semiconductor section 27D includes a portion that overlaps the lower layer gate electrode 27A and a portion that overlaps the upper layer gate electrode 27E. A detailed configuration of the TFT 27 will be described later. The pixel electrode 28 is disposed in an area surrounded by two sets of the overlapping gate lines 25, 29 that are adjacent to each other at an interval in the Y-axis direction and two source lines 26 that are adjacent to each other at an interval in the X-axis direction. The pixel electrode 28 has a vertically long rectangular shape with a long-side direction thereof corresponding to the Y-axis direction. The pixel electrode 28 and a color filter that is included in the opposed substrate 20 or the array substrate 21 are configured as a pixel, which is a display unit.

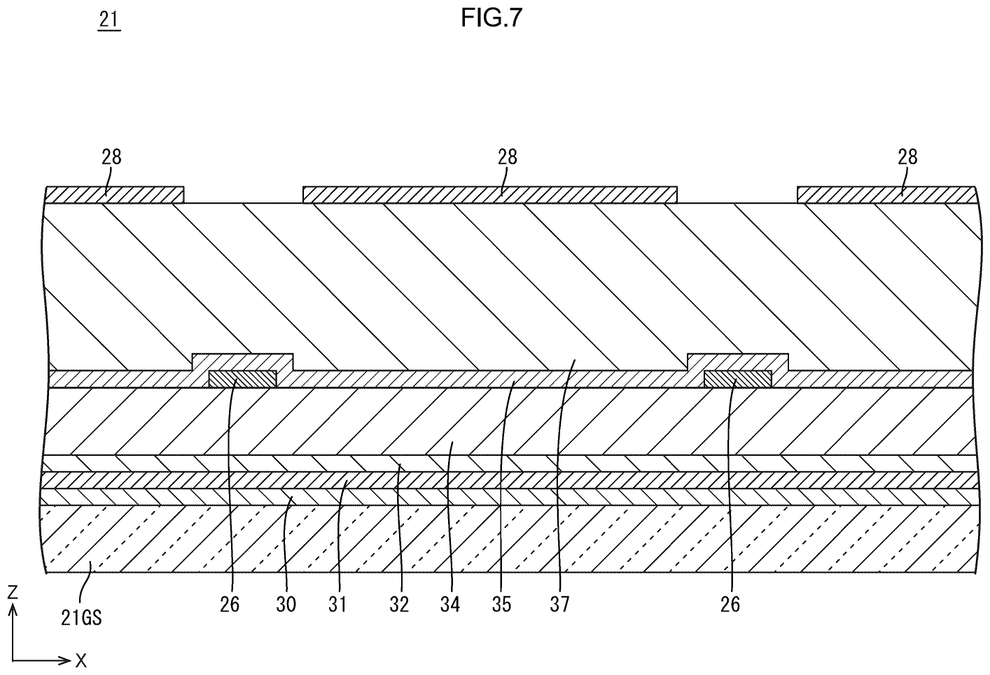

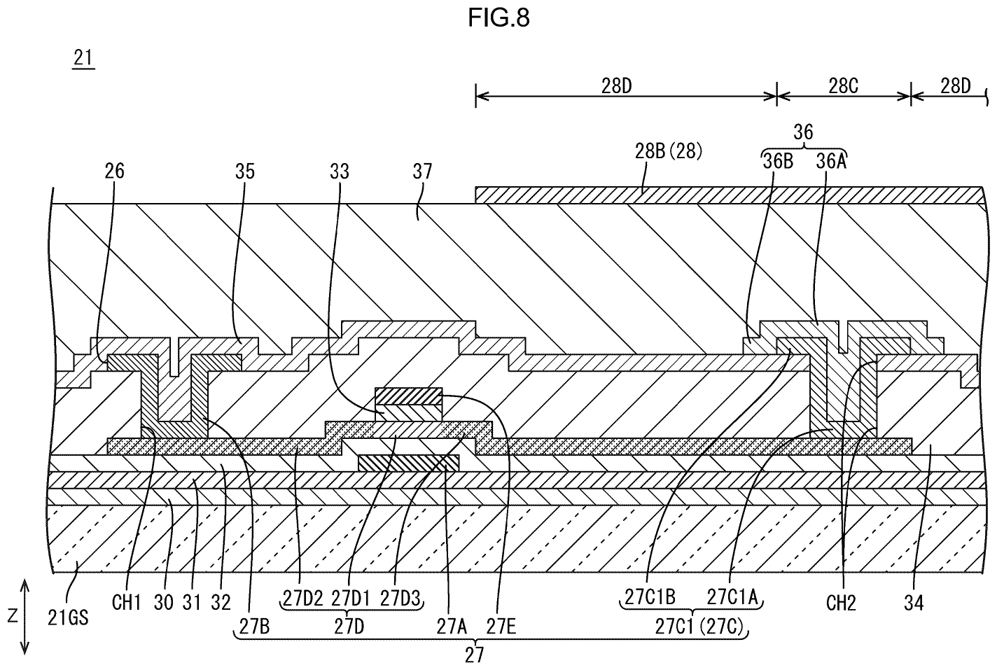

Next, various films that are disposed in layers on the glass substrate 21GS of the array substrate 21 will be described in detail with reference to FIGS. 7 and 8. As illustrated in FIGS. 7 and 8, on the glass substrate 21GS of the array substrate 21, the following films are at least disposed on top of each other in the following order from the lowest layer (the grass substrate 21GS side): a basecoat film 30, a first semiconductor film, a first gate insulation film 31, a first metal film, a second gate insulation film 32 (a fourth insulation film), a second semiconductor film, a third gate insulation film 33 (a fifth insulation film), a second metal film, a first interlayer insulation film 34 (a first insulation film), a third metal film, a second interlayer insulation film 35 (the first insulation film), a first transparent electrode film, a third interlayer insulation film 36 (a second insulation film), a first planarization film 37 (a third insulation film), a second transparent electrode film, a second planarization film 38, and a third transparent electrode film. An alignment film for orienting liquid crystal molecules included in the liquid crystal layer 22 is disposed on a most inner surface of the array substrate 21 that faces the liquid crystal layer 22.

Each of the first metal film, the second metal film, and the third metal film is a single-layer film made of one kind of metal, a multilayer film made of different kinds of metals (conductive materials), or alloy, and has electrically conductive properties and light blocking properties. The first metal film may be a single-layer film made of molybdenum tungsten (MoW) or a multilayer film made of a tungsten (W) layer and a tantalum nitride (TaN) layer, for instance. As illustrated in FIGS. 7 and 8, portions of the first metal film are configured as the lower layer gate lines 25 and the lower layer gate electrodes 27A. The second metal film is a multilayer film made of a titanium (Ti) layer, an aluminum (Al) layer, and a Ti layer. Portions of the second metal film are configured as the upper layer gate lines 29 and the upper layer gate electrodes 27E. The third metal film is a multilayer film made of a titanium layer (Ti), an aluminum (Al) layer, and a Ti layer. Portions of the third metal film are configured as the source lines 26. The first transparent electrode film, the second transparent electrode film, and the third transparent electrode film are made of transparent electrode material such as indium tin oxide (ITO) and indium zinc oxide (IZO). Portions of the first transparent electrode film are configured as the drain electrodes 27C. Portions of the second transparent electrode film and the third transparent electrode film are configured as the pixel electrodes 28.

The first semiconductor film is made of silicon semiconductor material, for instance. More specifically, the semiconductor film may be a thin film of a CG silicon (continuous grain silicon) that is a kind of polycrystallized silicon (polycrystalline silicon). The CG silicon thin film is prepared by adding metal material to an amorphous silicon thin film and heating the amorphous silicon at a low temperature of 550° or lower for a short time. This provides continuity of the atomic arrangement at the silicon grain boundaries. The silicon semiconductor material of the first semiconductor film has higher electron mobility than the oxide semiconductor material. With using such a first conductive film, the circuit component such as a TFT included in the circuit 14 disposed in the non-display area NAA can be formed. A portion of the semiconductor film is configured as a semiconductor portion of the circuit component such as a TFT included in the circuit 14. This accelerates the switching speed of the TFT included in the circuit 14 and display errors such as flicker and an afterimage are less likely to be caused on the image displayed with the pixel electrodes 28 in the display area AA. A portion of the first metal film may be configured as a gate electrode of the TFT included in the circuit 14. Portions of the third metal film may be configured as a source electrode and a drain electrode of the TFT included in the circuit 14.

The second semiconductor film is made of oxide semiconductor material. In detail, the second semiconductor film is an oxide semiconductor thin film including indium (In), gallium (Ga), and zinc (Zn), which are one kind of oxide semiconductor. The oxide semiconductor thin film including indium (In), gallium (Ga), and zinc (Zn) is non-crystalline or crystalline. The oxide semiconductor material of the second semiconductor film has a higher resistance value with no voltage being applied (OFF state) compared to silicon semiconductor material. The oxide semiconductor material of the second semiconductor film has higher electron mobility than the amorphous silicon semiconductor material. Portions of the second semiconductor film are configured as the semiconductor sections 27D of the TFTs 27. With the TFTs 27 disposed in the display area AA being configured with using the second semiconductor film, leakage current in the OFF state of the TFTs 27 is reduced. This reduces power consumption. Furthermore, the TFT 27 can be miniaturized and precision of the liquid crystal panel 11 can be preferably increased. Particularly, the liquid crystal panel 11 is preferably included in the head-mounted display 10HMD.

As illustrated in FIG. 8, a portion of the semiconductor section 27D of the TFT 27 that is a portion of the second semiconductor film is made electrically conductive (resistance lowered). In FIG. 8, the electrically conductive portion of the semiconductor section 27D is illustrated with shading. A portion of the semiconductor section 27D that is not made electrically conductive is defined as a non-conductive section 27D1 (a resistance non-lowered section). The non-conductive section 27D1 is a portion of the semiconductor section 27D that overlaps the upper layer gate electrode 27E. Electrons can move through the non-conductive section 37D1 under a particular condition (when the scanning signals are supplied to the gate electrodes 27A, 27E). Namely, the non-conductive section 27D1 functions as a channel section under the particular condition. The conductive section (a conductive section, a resistance-lowered section) of the semiconductor section 27D is defined as the source section 27D2 (a first conductive section) and a drain section 27D3 (a second conductive section). The source section 27D2 and the drain section 27D3 correspond to the portions of the semiconductor section 27D that do not overlap the upper layer gate electrode 27E of the semiconductor section 27D. The resistivity of the source section 27D2 and the drain section 27D3 is quite lower than that of the non-conductive section 27D1 and is about 1/10,000,000,000 to 1/100 of the resistivity of the non-conductive section 27D1. Electrons can always move through the source section 27D2 and the drain section 27D3 and the source section 27D2 and the drain section 27D3 function as electrically conductive members. In the process of producing the array substrate 21, after forming the upper layer gate lines 29 and the upper layer gate electrodes 27E that are portions of the second metal film, the semiconductor film is subjected to a process to be electrically conductive (subjected to a resistance lowering process) with using the upper layer gate lines 29 and the upper layer gate electrodes 27E as a mask. In the process to be electrically conductive, the portions of the semiconductor film that are not covered by the upper layer gate lines 29 and the upper layer gate electrodes 27E (non-overlapping portions, uncovered portions) are subjected to the process to be electrically conductive and the portions of the semiconductor film that are covered by the upper layer gate lines 29 and the upper layer gate electrodes 27E (overlapping portions, covered portions) are not subjected to the process to be electrically conductive. Examples of the process to be electrically conductive include a plasma surface treatment and an annealing treatment with using gas such as NH₃, H₂, N₂, He.

Each of the basecoat film 30, the first gate insulation film 31, the second gate insulation film 32, the third gate insulation film 33, the first interlayer insulation film 34, and the second interlayer insulation film 35 is made of inorganic insulation material (inorganic material) such as SiO₂ (silicon dioxide, silicon oxide) and SiNₓ (silicon nitride). The third interlayer insulation film 36 is made of inorganic insulation material (inorganic material) such as SiNₓ (silicon nitride). The basecoat film 30 is directly disposed on the glass substrate 21GS and included in a layer lower than the first semiconductor film. The first gate insulation film 31 is in a layer upper than the first semiconductor film and lower than the first metal film. For instance, the first gate insulation film 31 keeps insulation between the gate electrode and the semiconductor portion included in the circuit 14. The second gate insulation film 32 is made of SiO₂, for instance. The second gate insulation film 32 is in a layer upper than the first metal film and lower than the second semiconductor film. The second gate insulation film 32 keeps insulation between the lower layer gate electrode 27A and the semiconductor section 27D of the TFT 27. The third gate insulation film 33 is made of SiO₂, for instance. The third gate insulation film 33 is in a layer upper than the second semiconductor film and lower than the second metal film. The third gate insulation film 33 keeps insulation between the semiconductor section 27D and the upper layer gate electrode 27E of the TFT 27. The first interlayer insulation film 34 is in a layer upper than the second metal film and lower than the third metal film. The first interlayer insulation film 34 is made of SiO₂, for instance. The first interlayer insulating film 34 and the second gate insulation film 32 keep insulation between the lower layer gate line 25 and the source line 26. The first interlayer insulation film 34 keeps insulation between the upper layer gate line 29 and the source line 26. The second interlayer insulation film 35 is in a layer upper than the third metal film and lower than the first transparent electrode film. The second interlayer insulation film 35 and the first interlayer insulation film 34 keep insulation between the drain electrode 27C and the upper layer gate line 29. The third interlayer insulation film 36 is in a layer upper than the first transparent electrode film and lower than the first planarization film 37. The third interlayer insulation film 36 will be described in detail later.

The first planarization film 37 and the second planarization film 38 are made of organic insulation material (organic material) such as PMMA (acrylic resin). The first planarization film 37 and the second planarization film 38 that are made of organic insulation material have a film thickness greater than that of the basecoat film 30, the first gate insulation film 31, the second gate insulation film 32, the third gate insulation film 33, the first interlayer insulation film 34, the second interlayer insulation film 35, and the third interlayer insulation film 36 that are made of inorganic insulation material. Specifically, the thickness of the basecoat film 30, the first gate insulation film 31, the second gate insulation film 32, the third gate insulation film 33, the first interlayer insulation film 34, the second interlayer insulation film 35, and the third interlayer insulation film 36 that are made of inorganic insulation material is about several dozen nm to several hundred nm, for instance. The thickness of the first planarization film 37 and the second planarization film 38 is about 1 μm to 3 μm. The first planarization film 37 is in a layer upper than the second interlayer insulation film 35 and lower than the second transparent electrode film. The first planarization film 37 keeps insulation between the drain electrode 27C and the pixel electrode 28. The second planarization film 38 is in a layer upper than the second transparent electrode film and lower than the third transparent electrode film.

With the liquid crystal panel 11 operating in the fringe field switching (FFS) mode, for instance, the array substrate 21 includes a fourth interlayer insulation film in a layer upper than the third transparent electrode film and a fourth transparent electrode film in a layer upper than the fourth interlayer insulation film. In such a configuration, the fourth transparent electrode film is configured as a common electrode having a common potential. With the liquid crystal panel 11 operating in the vertical alignment (VA) mode or the twisted nematic (TN) mode, the opposed substrate 20 includes an opposed electrode.

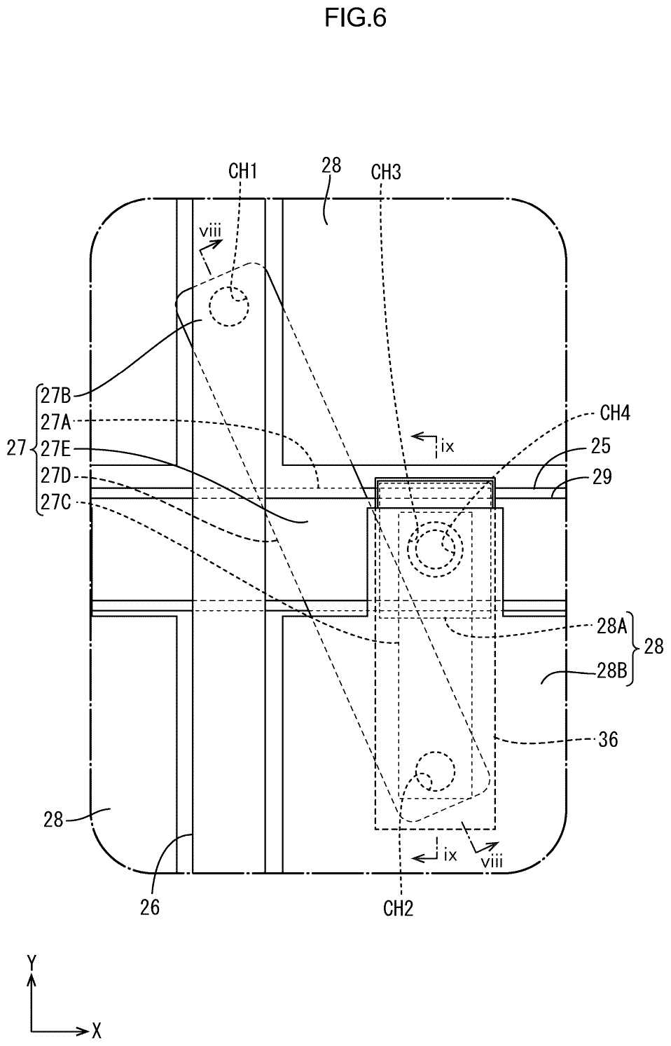

Next, the configuration of the TFTs 27 will be described in detail. As illustrated in FIGS. 6 and 8, the semiconductor section 27D of the TFT 27 extends in an oblique direction with respect to the X-axis direction and the Y-axis direction and crosses the gate lines 25, 29 and the source line 26. A middle portion of the semiconductor section 27D with respect to the extending direction (the oblique direction) of the semiconductor section 27D overlaps the lower layer gate electrode 27A and the upper layer gate electrode 27E. A portion of the middle portion of the semiconductor section 27D with respect to the extending direction that overlaps the upper layer gate electrode 27E is defined as the non-conductive section 27D1. One of the end portions of the semiconductor section 27D with respect to the extending direction that crosses the source line 26 (the source electrode 27B) is defined as the source section 27D2. Other one of the end portions of the semiconductor section 27D with respect to the extending direction that crosses the drain electrode 27C is defined as the drain section 27D3.

As illustrated in FIG. 8, the non-conductive section 27D1 of the semiconductor section 27D overlaps the lower layer gate electrode 27A via the second gate insulation film 32 and is in a layer upper than the lower layer gate electrode 27A. The non-conductive section 27D1 of the semiconductor section 27D overlaps the upper layer gate electrode 27E via the third gate insulation film 33 and is in a layer lower than the upper layer gate electrode 27E. Thus, the TFTs 27 according to this embodiment have a double gate structure in which the non-conductive section 27D1 of the semiconductor section 27D is sandwiched between the upper layer gate electrode 27E and the lower layer gate electrode 27A. With the TFT 27 being driven based on the scanning signals supplied from the lower layer gate line 25 and the upper layer gate line 29 to the lower layer gate electrode 27A and the upper layer gate electrode 27E, respectively, two channel sections are created in an upper layer portion and a lower layer portion of the non-conductive section 27D1 of the semiconductor section 27D. The image signal supplied from the source line 26 to the source electrode 27B is supplied to the drain electrode 27C via the channel sections of the non-conductive section 27D1 of the semiconductor section 27D. Thus, the pixel electrode 28 is charged at a potential based on the image signal. Since the semiconductor section 27D includes the two channel sections, the electron mobility becomes higher.

As illustrated in FIG. 8, a first end portion of the source section 27D2 of the semiconductor section 27D that is opposite from a second end portion thereof close to the non-conductive section 27D1 overlaps the source electrode 27B, which is a portion of the source line 26, via the first interlayer insulation film 34. The first end portion of the source section 27D2 is in a layer lower than the source electrode 27B. The first interlayer insulation film 34 includes a source contact hole CH1 in a portion overlapping the source section 27D2 and the source electrode 27B. The source section 27D2 and the source electrode 27B are connected via the source contact hole CH1.

As illustrated in FIG. 8, a first end portion of the drain section 27D3 of the semiconductor section 27D that is opposite from a second end portion thereof close to the non-conductive section 27D1 overlaps a portion of the drain electrode 27C via the first interlayer insulation film 34 and the second interlayer insulation film 35. The first end portion of the drain section 27D3 is in a layer lower than the drain electrode 27C. Each of the first interlayer insulation film 34 and the second interlayer insulation film 35 includes a drain contact hole CH2 (a first contact hole) in a portion thereof overlapping the drain section 27D3 and the drain electrode 27C. The drain contact holes CH2 in the first interlayer insulation film 34 and the second interlayer insulation film 35 are communicated with each other. The drain section 27D3 and the drain electrode 27C are connected via the drain contact holes CH2.

As illustrated in FIG. 5, the drain electrode 27C extends along the Y-axis direction and has a vertically long rectangular plan view shape. The drain electrode 27C is disposed in a middle of the two source lines 26 that are arranged at an interval in the X-axis direction (a middle of the pixel electrode 28 in the X-axis direction). An entire area of the drain electrode 27C overlaps the pixel electrode 28 to be connected. As illustrated in FIGS. 6 and 8, a first end portion (a lower end portion in FIG. 6) of the drain electrode 27C with respect to the Y-axis direction overlaps the drain section 27D3 of the semiconductor section 27D and is connected to the drain section 27D3 via the drain contact holes CH2. The first end portion of the drain electrode 27C with respect to the Y-axis direction is configured as a first connection portion 27C1 that is connected to the drain section 27D3. The first connection portion 27C1 includes a first overlapping portion 27C1A that overlaps the drain contact holes CH2 and a surrounding portion 27C1B that is a portion around the first overlapping portion 27C1A.

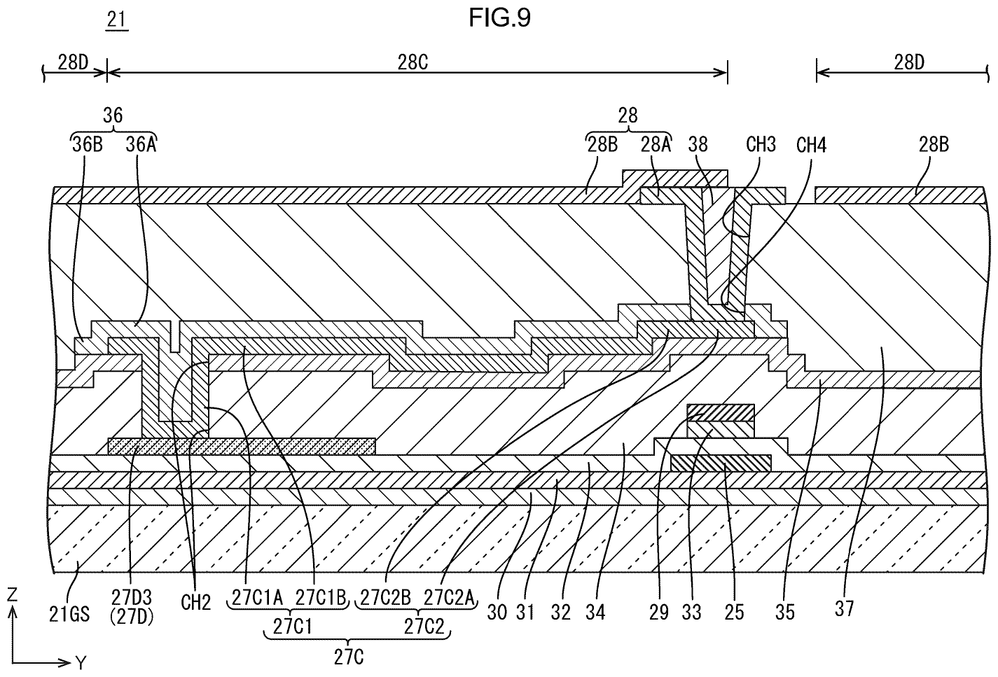

As illustrated in FIGS. 5 and 9, the pixel electrode 28 includes a connection portion 28A that is connected to the drain electrode 27C and a pixel body portion 28B that is connected to the connection portion 28A. The connection portion 28A is a portion of the second transparent electrode film and has an island shape so as to overlap a portion of the drain electrode 27C. A second end portion (au upper end portion in FIG. 5) of the drain electrode 27C with respect to the Y-axis direction overlaps the connection portion 28A of the pixel electrode 28 and is configured as a second connection portion 27C2 that is connected to the connection portion 28A. The first planarization film 37 is between the connection portion 28A, which is a portion of the second transparent electrode film, and the second connection portion 27C2, which is a portion of the first transparent electrode film. The first planarization film 37 includes a first pixel contact hole CH3 (a second contact hole) in a portion overlapping the connection portion 28A and the second connection portion 27C2. The first pixel contact hole CH3 is spaced from the drain contact hole CH2 in the Y-axis direction so as not to overlap the drain contact hole CH2. The connection portion 28A and the second connection portion 27C2 are connected via the first pixel contact hole CH3. The second connection portion 27C2 includes a second overlapping portion 27C2A that overlaps the first pixel contact hole CH3 and a surrounding portion 27C2B that is a portion around the second overlapping portion 27C2A.

As illustrated in FIG. 5, the pixel body portion 28B is a portion of the third transparent electrode film. The pixel body portion 28B is configured as a most portion of the pixel electrode 28. An electric field is created between the pixel body portion 28B and the common electrode or the opposed electrode. The pixel body portion 28B is disposed in an area surrounded by two sets of the gate lines 25, 29 that are adjacent to each other at an interval in the Y-axis direction and two source lines 26 that are adjacent to each other at an interval in the X-axis direction. The pixel body portion 28B has a vertically elongated rectangular shape. A portion of the pixel body portion 28B overlaps substantially an entire area of the connection portion 28A and most portion of the rest of the pixel body portion 28B does not overlap the connection portion 28A. As illustrated in FIG. 9, the second planarization film 38 is disposed between the pixel body portion 28B, which is a portion of the third transparent electrode film, and the connection portion 28A, which is a portion of the second transparent electrode film. The second planarization film 38 is selectively disposed so as to cover a portion of the connection portion 28A overlapping the first pixel contact hole CH3. The portion of the connection portion 28A overlapping the first pixel contact hole CH3 is recessed into the first pixel contact hole CH3 unlike other portion of the connection portion 28A. The second planarization film 38 is provided for filling the recessed portion of the connection portion 28A and thus, an upper surface (a surface) of the connection portion 28A is planarized. No second planarization film 38 is formed in an area that does not overlap the first pixel contact hole CH3. Therefore, portions of the pixel body portion 28B and the connection portion 28A that do not overlap the first pixel contact hole CH3 are directly contacted and connected to each other without intervening the second planarization film 38.

As illustrated in FIGS. 6 and 9, the pixel electrode 28 includes an electrode overlapping section 28C that overlaps the drain electrode 27C and an electrode non-overlapping section 28D that does not overlap the drain electrode 27C. The electrode overlapping section 28C includes a most portion of the connection portion 28A and a portion of the pixel body portion 28B. The electrode non-overlapping section 28D includes a portion of the connection portion 28A and a most portion of the pixel body portion 28B.

As illustrated in FIG. 8, the semiconductor section 27D of the TFT 27 is covered by the second interlayer insulation film 35 from an upper layer side. Therefore, impurities such as moistures included in the first planarization film 37, which is made of organic insulation material, are less likely to directly enter and spread into the semiconductor section 27D. The semiconductor section 27D is connected to the first overlapping portion 27C1A of the drain electrode 27C via the drain contact hole CH2 in the second interlayer insulation film 35. The drain electrode 27C that is made of transparent electrode material can transmit light. Therefore, light rays passing through the electrode non-overlapping section 28D of the pixel electrode 28 and also light rays passing through the electrode overlapping portion 28C can be used for displaying. Therefore, light transmittance of the pixel electrode 28 is improved compared to a drain electrode made of metal material. On the other hand, impurities included in the first planarization film 37 made of organic insulation material are likely to enter the drain electrode 27C made of transparent electrode material compared to the drain electrode made of metal material. Therefore, impurities may spread into the semiconductor section 27D via the drain electrode 27C.

In this respect, as illustrated in FIG. 6, the array substrate 21 of this embodiment includes the third interlayer insulation film 36 made of inorganic insulation material. The third interlayer insulation film 36 is in a layer upper than the drain electrode 27C and lower than the first planarization film 37. The third interlayer insulation film 36 is disposed to cover at least the first overlapping portion 27C1A of the drain electrode 27C. Therefore, impurities included in the first planarization film 37 are less likely to pass through the third interlayer insulation film 36 that is between the first planarization film 37 and the drain electrode 27C and less likely to reach the first overlapping portion 27C1A of the drain electrode 27C. Accordingly, the impurities included in the first planarization film 37 are less likely to spread into the semiconductor section 27D via the drain n electrode 27C. Therefore, characteristics of the TFTs 27 are less likely to change and operation errors are less likely to occur in the TFTs 27. In this embodiment, the third interlayer insulation film 36 is a single layer made of SiNₓ and has higher density compared to a third interlayer insulation film of a single layer made of SiO₂. Therefore, the impurities such as moisture are less likely to pass through the third interlayer insulation film 36 and are less likely to spread into the semiconductor section 27D.

As illustrated in FIGS. 6 and 9, the third interlayer insulation film 36 is disposed to cover substantially an entire area of the drain electrode 27C. Specifically, the third interlayer insulation film 36 extends along the Y-axis direction and has a vertically long rectangular plan view shape. Namely, the third interlayer insulation film 36 has an island plan view shape similar to the shape of the drain electrode 27C. The island-shaped third interlayer insulation films 36 are arranged in a matrix in the display area AA of the array substrate 21. The number of the island-shaped third interlayer insulation films 36 is same as that of the TFTs 27 (the pixel electrodes 28). The third interlayer insulation film 36 includes a second pixel contact hole CH4 (a third contact hole) in a portion overlapping the first pixel contact hole CH3 so as to be communicated with the first pixel contact hole CH3. The third interlayer insulation film 36 covers almost entire area of the drain electrode 27C except for the second overlapping portion 27C2A that overlaps the first pixel contact hole CH3. With such a configuration, the connection portion 28A of the pixel electrode 28 is connected to the second overlapping portion 27C2A of the drain electrode 27C via the first pixel contact hole CH3 in the first planarization film 37 and the second pixel contact hole CH4 in the third interlayer insulation film 36. Since the entire area of the drain electrode 27C except for the second overlapping portion 27C2A is covered by the third interlayer insulation film 36, impurities included in the first planarization film 37 are less likely to enter any portions of the drain electrode 27C. Accordingly, impurities are further less likely to spread into the semiconductor section 27D via the drain electrode 27C.

As illustrated in FIGS. 6 and 9, the third interlayer insulation film 36 is formed in an area overlapping the electrode overlapping section 28C of the pixel electrode 28 but is not formed in an area overlapping the electrode non-overlapping section 28D. With such a configuration, the amount of light rays absorbed by the third interlayer insulation film 36 reduces compared to a configuration in which a third interlayer insulation film is disposed in a solid manner and in the area overlapping the electrode non-overlapping section 28D. With the amount of light rays absorbed by the third interlayer insulation film 36 being reduced, the amount of light rays passing through the electrode non-overlapping section 28D increases and the amount of light rays reflecting off the interface (a lower surface of the third interlayer insulation film 36) of the third interlayer insulation film 36 and the drain electrode 27C and the interface (an upper surface of the third interlayer insulation film 36) of the third interlayer insulation film 36 and the first planarization film 37 reduces. The electrode non-overlapping section 28D includes most portion of the pixel body portion 28B and greatly influences the displaying of the pixels. Therefore, with the third interlayer insulation film 36 being not formed in the area overlapping the electrode non-overlapping section 28D, the light transmittance of the pixel electrode 28 increases and the displaying of the pixels is improved.

As illustrated in FIGS. 6, 8, and 9, the third interlayer insulation film 36 is disposed in an area larger than the area of the drain electrode 27C in a plan view. More in detail, the third interlayer insulation film 36 includes a first insulation portion 36A that overlaps the drain electrode 27C and a second insulation portion 36B that surrounds the first insulation portion 36A. With such a configuration, an entire periphery of the outer end portion of the drain electrode 27C is surrounded by the second insulation portion 36B of the third interlayer insulation film 36. Accordingly, impurities included in the first planarization film 37 are less likely to enter the outer end portion of the drain electrode 27C and therefore, the impurities are further less likely to spread into the semiconductor section 27D via the drain electrode 27C.

As illustrated in FIG. 6, the pixel electrode 28 is disposed such that a portion of the electrode overlapping section 28C overlaps the gate lines 25, 29. The second overlapping portion 27C2A of the drain electrode 27C is disposed to overlap the portion of the electrode overlapping section 28C that overlaps the gate lines 25, 29. Namely, the first planarization film 37 is disposed such that the first pixel contact hole CH3 overlaps the gate lines 25, 29. The third interlayer insulation film 36 is disposed such that the second pixel contact hole CH4 overlaps the gate lines 25, 29. The connection portion 28A of the pixel electrode 28 is connected to the second overlapping portion 27C2A of the drain electrode 27C via the first pixel contact hole CH3 in the first planarization film 37 and the second pixel contact hole CH4 in the third interlayer insulation film 36. Since the first pixel contact hole CH3 overlaps the gate lines 25, 29, light rays travelling toward the first pixel contact hole CH3 and the second pixel contact hole CH4 can be blocked by the gate lines 25, 29 that are made of metal material having light blocking properties. Accordingly, even if orientation errors of the liquid crystal molecules occur near the first pixel contact hole CH3 and the second pixel contact hole CH4, display quality is less likely to be deteriorated due to the orientation errors.

As previously described, the array substrate 21 of this embodiment includes the semiconductor section 27D that is made of semiconductor material, the first interlayer insulation film 34 and the second interlayer insulation film 35 that are the first insulation films and are disposed in layers upper than the semiconductor section 27D, the drain electrode 27C (the first electrode) disposed in a layer upper than the first interlayer insulation film 34 and the second interlayer insulation film 35, which are the first insulation films, and a portion of the drain electrode 27C being overlapped with a portion of the semiconductor section 27D, the third interlayer insulation film 36 (the second insulation film) included in a layer upper than the drain electrode 27C, and the first planarization film 37 (the third insulation film) included in a layer upper than the third interlayer insulation film 36. The drain electrode 27C is made of transparent electrode material. The first interlayer insulation film 34 and the second interlayer insulation film 35, which are the first insulation film, are made of inorganic insulation material and include the drain contact holes CH2 (the first contact hole) in portions overlapping the semiconductor section 27D and the drain electrode 27. The drain contact holes CH2 are for connecting the semiconductor section 27D and the drain electrode 27C. The first planarization film 37 is made of organic insulation material. The third interlayer insulation film 36 is made of inorganic insulation material and at least covers the first overlapping portion 27C1A of the drain electrode 27C that overlaps the drain contact hole CH2.

The semiconductor section 27D is covered by the first interlayer insulation film 34 and the second interlayer insulation film 35, which are the first insulation film, from the upper layer side. Therefore, impurities such as moisture included in the first planarization film 37 made of organic insulation material are less likely to directly enter or spread into the semiconductor section 27D. The semiconductor section 27D is connected to the first overlapping portion 27C1A of the drain electrode 27C via the drain contact holes CH2 in the first interlayer insulation film 34 and the second interlayer insulation film 35, which are the first insulation film. The drain electrode 27C that is made of transparent electrode material can transmit light. With such a configuration, light transmittance is improved. On the other hand, the impurities included in the first planarization film 37 made of organic insulation material are likely to pass through the drain electrode 27C made of transparent electrode material. Therefore, the impurities may spread into the semiconductor section 27D via the drain electrode 27C. In this respect, the third interlayer insulation film 36 made of inorganic insulation material is between the drain electrode 27C and the first planarization film 37 and the third interlayer insulation film 36 covers at least the first overlapping portion 27C1A of the drain electrode 27C that overlaps the drain contact hole CH2. Therefore, the impurities included in the first planarization film 37 are less likely to enter the first overlapping portion 27C1A. Accordingly, the impurities are less likely to spread into the semiconductor section 27D via the drain electrode 27C.

The array substrate 21 of this embodiment further includes the pixel electrode 28 disposed in a layer upper than the first planarization 7 and disposed such that a portion of the pixel electrode 28 overlaps the drain electrode 27C. The first planarization film 37 includes the first pixel contact hole CH3 (the second contact hole) in a portion overlapping the drain electrode 27C and the pixel electrode 28 and not overlapping the drain contact hole CH2. The drain electrode 27C and the pixel electrode 28 are connected via the first pixel contact hole CH3. The third interlayer insulation film 36 includes the second pixel contact hole CH4 (the third contact hole) that is communicated with the first pixel contact hole CH3. The third interlayer insulation film 36 covers an entire area of the drain electrode 27C except for the second overlapping portion 27C2A that overlaps the first pixel contact hole CH3. The pixel electrode 28 is connected to the second overlapping portion 27C2A of the drain electrode 27C via the first pixel contact hole CH3 in the first planarization film 37 and the second pixel contact hole CH4 in the third interlayer insulation film 36. The entire area of the drain electrode 27C except for the second overlapping portion 27C2A is covered by the third interlayer insulation film 36 and therefore, impurities included in the first planarization film 37 are less likely to enter any portions of the drain electrode 27C. Accordingly, the impurities are further less likely to spread into the semiconductor section 27D via the drain electrode 27C.

The third interlayer insulation film 36 includes the first insulation portion 36A that overlaps the drain electrode 27C and the second insulation portion 36B that surrounds the first insulation portion 36A. With such a configuration, the outer edge portion of the drain electrode 27C is surrounded by the second insulation portion 36B of the third interlayer insulating film 36. Accordingly, the impurities included in the first planarization film 37 are less likely to enter the outer edge portion of the drain electrode 27C and the impurities are further less likely to spread into the semiconductor section 27D via the drain electrode 27C.

The pixel electrode 28 includes the electrode overlapping section 28C that overlaps the drain electrode 27C and the electrode non-overlapping section 28D that does not overlap the drain electrode 27C. The third interlayer insulation film 36 is not formed in an area overlapping the electrode non-overlapping section 28D. With such a configuration, the amount of light rays absorbed by the third interlayer insulation 36 film reduces compared to a configuration in which a third interlayer insulation film is also disposed in the area overlapping the electrode non-overlapping section 28D. Accordingly, the amount of light rays passing through the electrode non-overlapping section 28D of the pixel electrode 28 increases and the amount of light rays reflecting off the interface of the third interlayer insulation film 36 reduces. Accordingly, the light transmittance of the pixel electrode 28 increases.

The array substrate 21 of this embodiment further includes the pixel electrode 28 and the lower layer gate line 25 (the first line). The pixel electrode 28 is disposed in a layer upper than the first planarization film 37 such that a portion of the pixel electrode 28 overlaps the drain electrode 27C. The lower layer gate line 25 is made of conductive material having light blocking properties and disposed in a layer lower than the first interlayer insulation film 34 and the second interlayer insulation film 35, which are the first insulation film. The first planarization film 37 includes the first pixel contact hole CH3 in a portion overlapping the drain electrode 27C and the pixel electrode 28 and the lower layer gate line 25. The drain electrode 27C and the pixel electrode 28 are connected via the first pixel contact hole CH3. The pixel electrode 28 is connected to the drain electrode 27C via the first pixel contact hole CH3 in the first planarization film 37. Since the first pixel contact hole CH3 is formed to overlap the lower layer gate line 25, light rays travelling toward the first pixel contact hole CH3 can be blocked by the lower layer gate line 25 that is made of conductive material having light blocking properties.

The third interlayer insulation film 36 includes SiNₓ as the inorganic insulation material and has higher density compared to a third interlayer insulation film including only SiO₂ as the inorganic insulation material. Therefore, the impurities such as moisture are less likely to pass through the third interlayer insulation film 36. Accordingly, impurities are less likely to spread into the semiconductor section 27D.

The array substrate 21 of this embodiment further includes the second gate insulation film 32 (the fourth insulation film) disposed in a layer lower than the semiconductor section 27D, the lower layer gate electrode 27A (the second electrode) disposed in a layer lower than the second gate insulation film 32 and disposed to overlap a portion of the semiconductor section 27D, and the source electrode 27B (the third electrode) disposed not to overlap the drain electrode 27C and the lower layer gate electrode 27A and connected to the semiconductor section 27D. The drain electrode 27C, the lower layer gate electrode 27A, the source electrode 27B, and the semiconductor section 27D are configured as the TFT 27 (the transistor). With the voltage of the threshold of the TFT 27 or higher being applied to the lower layer gate electrode 27A, the channel section is created in the semiconductor section 27D and electrons move between the drain electrode 27C and the source electrode 27B via the channel section. Since the impurities are less likely to spread into the semiconductor section 27D due to the first planarization film 37, the characteristics of the TFTs 27 are less likely to be changed. Accordingly, operation errors are less likely to be caused in the TFTs 27.

The array substrate 21 of this embodiment further includes the third gate insulation film 33 (the fifth insulation film), the upper layer gate electrode 27E (the fourth electrode), and the source electrode 27B. The third gate insulation film 33 is disposed in a layer upper than the semiconductor section 27D and lower than the first interlayer insulation film 34 and the second interlayer insulation film 35, which are the first insulation film. The upper layer gate electrode 27E is disposed in a layer upper than the third gate insulation film 33 and lower than the first interlayer insulation film 34 and the second interlayer insulation film 35, which are the first insulation film. The upper layer gate electrode 27E is disposed to overlap a portion of the semiconductor section 27D. The source electrode 27B is disposed not to overlap the drain electrode 27C and the upper layer gate electrode 27E and is connected to the semiconductor section. The drain electrode 27C, the upper layer gate electrode 27E, the source electrode 27B, and the semiconductor section 27D are configured as the TFT 27. With the voltage of a threshold of the TFT 27 or greater being applied to the upper layer gate electrode 27E, the channel section is created in the semiconductor section 27D and electrons move between the drain electrode 27C and the source electrode 27B via the channel section. Since the impurities are less likely to spread into the semiconductor section 27D due to the first planarization film 37, the characteristics of the TFTs 27 are less likely to be changed. Accordingly, operation errors are less likely to be caused in the TFTs 27.

The liquid crystal panel 11 (the display device) of this embodiment includes the array substrate 21 and the opposed substrate 20 disposed to be opposite the array substrate 21. According to such a liquid crystal panel 11, impurities are less likely to spread into the semiconductor section 27D included in the array substrate 21 and good display quality can be obtained.

### Second Embodiment

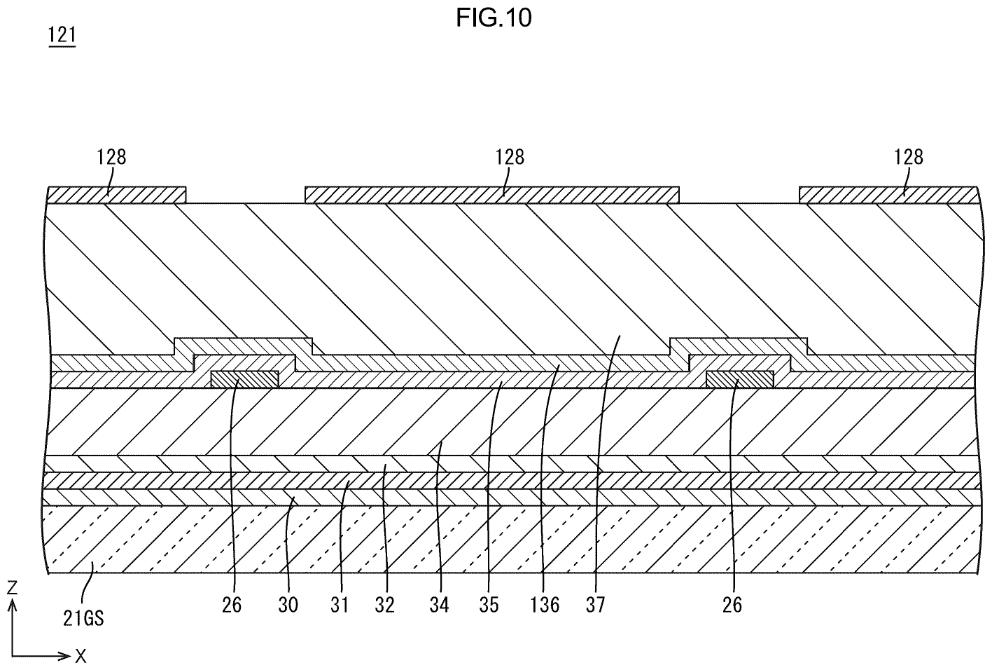

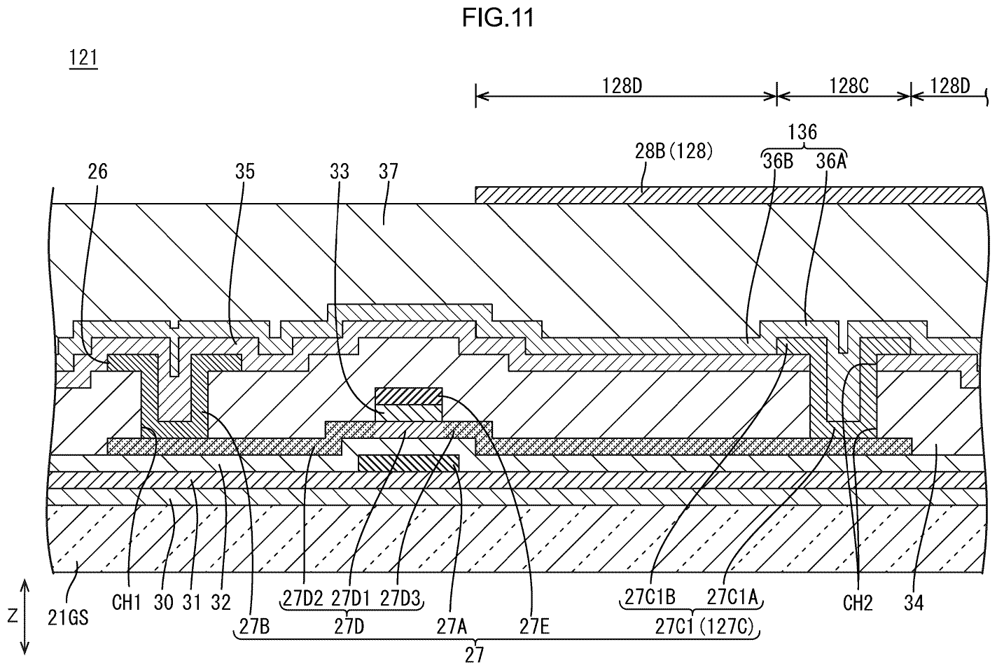

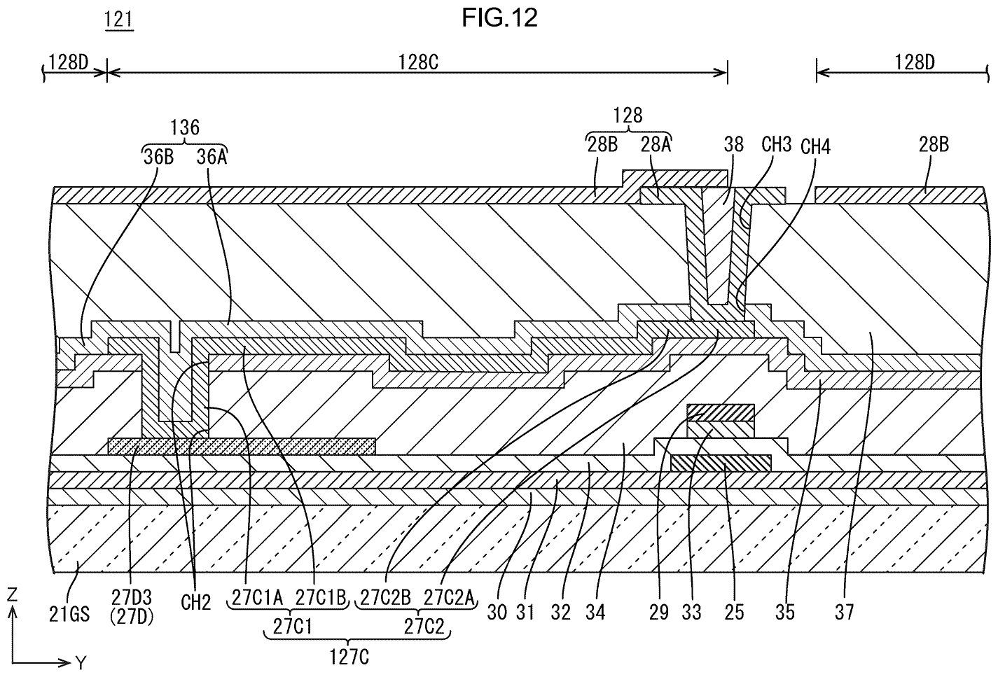

A second embodiment will be described with reference to FIGS. 10 to 12. In the second embodiment, the area where a third interlayer insulation film 136 is formed differs from the area where the third interlayer insulation film 36 is formed in the first embodiment. The configurations, operations, and effects of the second embodiment that are similar to those of the first embodiment will not be described.

As illustrated in FIGS. 10 to 12, the third interlayer insulation film 136 of this embodiment is disposed to extend in a solid manner in an entire area of at least the display area AA in an array substrate 121. The third interlayer insulation film 136 overlaps all of pixel electrodes 128 disposed in the display area AA. The third interlayer insulation film 136 is disposed to overlap an electrode non-overlapping section 128D in addition to an electrode overlapping section 128C of each pixel electrode 128. With the third interlayer insulation film 36 being not disposed in an area overlapping the electrode non-overlapping section 28D as is in the first embodiment 1 (refer to FIG. 6), the edge portion of the third interlayer insulation film 36 overlaps the pixel electrode 28; however, in this embodiment, the edge portion of the third interlayer insulation film 136 does not overlap the pixel electrode 128. With such a configuration, light rays that are refracted or reflected by the end portion of the third interlayer insulation film 136 are less likely to pass through the pixel electrode 128. The third interlayer insulation film 136 may be disposed only in the display area AA but may be disposed continuously in the display area AA and the non-display area NAA.

As described above, according to this embodiment, the pixel electrode 128 includes the electrode overlapping section 128C that overlaps a drain electrode 127C and the electrode non-overlapping section 128D that does not overlap the drain electrode 127C. The third interlayer insulation film 136 is formed in the area overlapping the electrode non-overlapping section 128D. With the third interlayer insulation film being not disposed in an area overlapping the electrode non-overlapping section 28D, the edge portion of the third interlayer insulation film 36 overlaps the pixel electrode 28; however, in this embodiment, the edge portion of the third interlayer insulation film 136 does not overlap the pixel electrode 128. With such a configuration, light rays that are refracted or reflected by the edge portion of the third interlayer insulation film 136 are less likely to pass through the pixel electrode 128.

### Third Embodiment

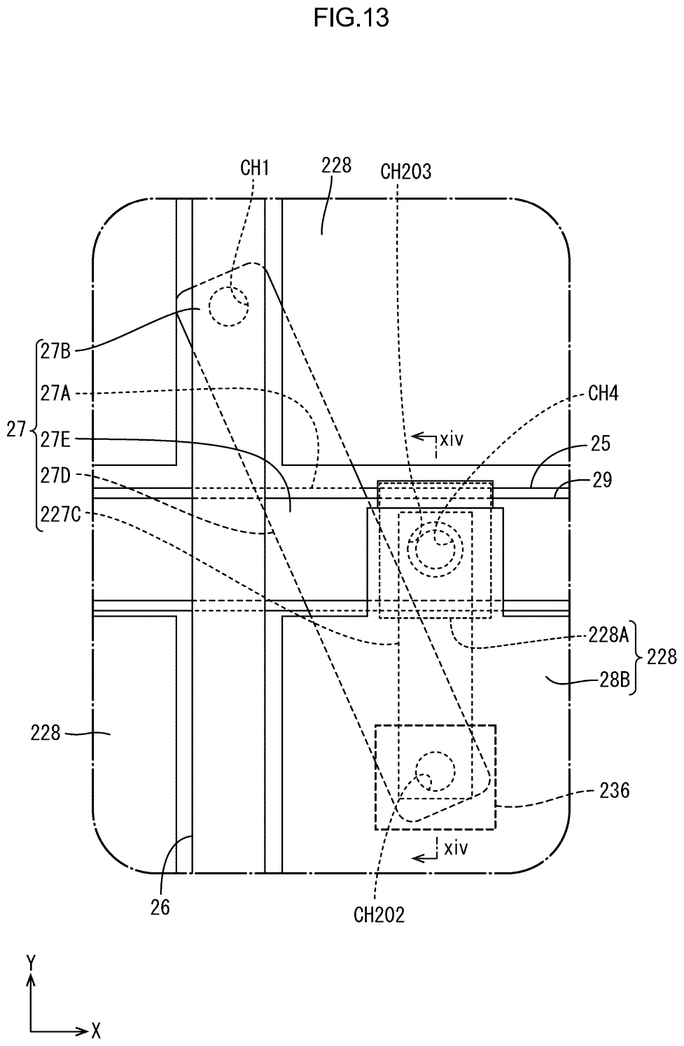

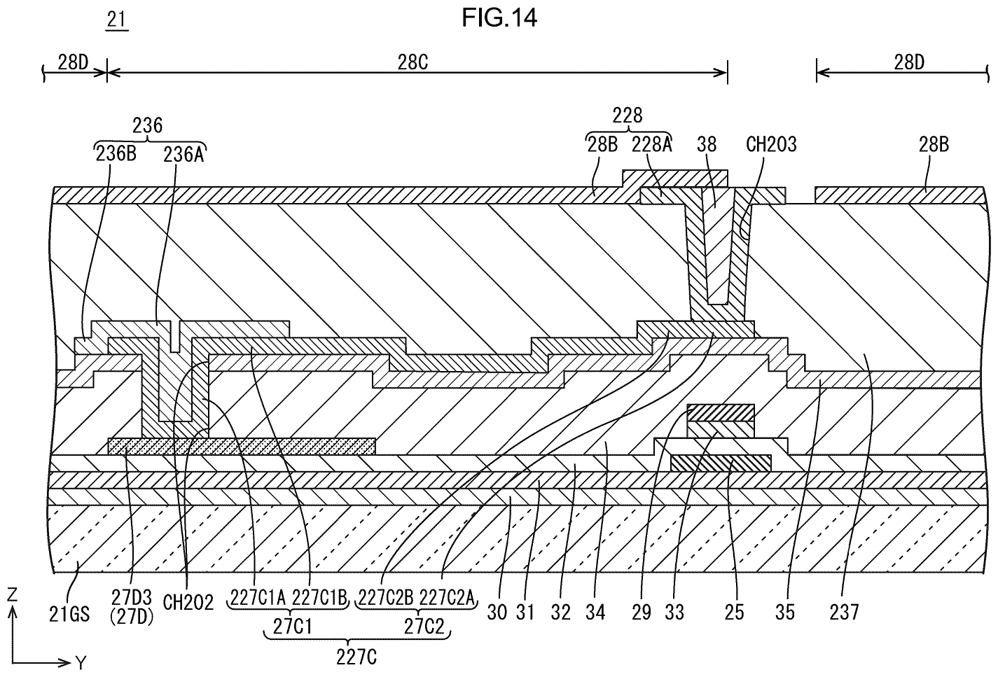

A third embodiment will be described with reference to FIGS. 13 and 14. In the third embodiment, the area where a third interlayer insulation film 236 is formed differs from the area where the third interlayer insulation film 36 is formed in the first embodiment. The configurations, operations, and effects of the third embodiment that are similar to those of the first embodiment will not be described.

As illustrated in FIGS. 13 and 14, the third interlayer insulation film 236 according to this embodiment is disposed to overlap a portion of a drain electrode 227C. Specifically, the third interlayer insulation film 236 is formed in areas respectively overlapping a first overlapping portion 227C1A and a surrounding portion 227C1B that is a portion of the drain electrode 227C around the first overlapping portion 227C1A. The first overlapping portion 227C1A is a portion of the drain electrode 227C overlapping a drain contact hole CH202. The third interlayer insulation film 236 is not formed in areas respectively overlapping a second overlapping portions 227C2A and a surrounding portion 227C2B that is a portion of the drain electrode 227C around the second overlapping portion 227C2A. The second overlapping portions 227C2A is a portion overlapping a first pixel contact hole CH203. The third interlayer insulation film 236 has a square plan view shape and is disposed such that a center of the third interlayer insulation film 236 matches centers of the drain contact hole CH202 and the first overlapping portion 227C1A. The third interlayer insulation film 236 extends further from the surrounding portion 227C1B of the first overlapping portion 227C1A and includes a portion that does not overlap the drain electrode 227C. Specifically, the third interlayer insulation film 236 includes a first insulation portion 236A that overlaps the first overlapping portion 227C1A and the surrounding portion 227C1B of the drain electrode 227C and a second insulation portion 236B that surrounds the first insulation portion 236A.

The first overlapping portion 227C1A and the surrounding portion 227C1B of the drain electrode 227C are covered by the third interlayer insulation film 236; however, the second overlapping portion 227C2A and the surrounding portion 227C2B of the drain electrode 227C are not covered by the third interlayer insulation film 236. Therefore, compared to the configuration of the first embodiment in which the entire area of the drain electrode 27C except for the second overlapping portion 27C2A is covered by the third interlayer insulation film 36 (refer to FIG. 6), the area in which the third interlayer insulation film 236 is formed is reduced. As the area in which the third interlayer insulation film 236 is formed is reduced, the amount of light rays absorbed by the third interlayer insulation film 236 reduces and the amount of light rays passing through a pixel electrode 228 increases and the amount of light rays reflecting off the interface (a lower surface of the third interlayer insulation film 236) of the third interlayer insulation film 236 and the drain electrode 227C and the interface (an upper surface of the third interlayer insulation film 236) of the third interlayer insulation film 236 and a first planarization film 237 reduces. Accordingly, the light transmittance of the pixel electrode 228 increases. The third interlayer insulation film 236 is not formed in an area overlapping a connection portion 228A of the pixel electrode 228 and therefore, the third interlayer insulation film 236 does not include the second pixel contact hole CH4 (refer to FIG. 9) of the first embodiment. The connection portion 228A is connected to the second overlapping portion 227C2A of the drain electrode 227 via the first pixel contact hole CH203 in the first planarization film 237.

As described above, this embodiment includes the pixel electrode 228 that is disposed in a layer upper than the first planarization film 237 and a portion of the pixel electrode 228 overlaps the drain electrode 227C. The first planarization film 237 includes the first pixel contact hole CH203 in a portion that overlaps the drain electrode 227C and the pixel electrode 228 and does not overlap the drain contact hole CH202. The drain electrode 227C and the pixel electrode 228 are connected via the first pixel contact hole CH203. The third interlayer insulation film 236 is formed to overlap the first overlapping portion 227C1A and the surrounding portion 227C1B of the drain electrode 227C that surrounds the first overlapping portion 227C1A. The third interlayer insulation film 236 is not formed in areas respectively overlapping the second overlapping portion 227C2A, which is a portion of the drain electrode 227C overlapping the first pixel contact hole CH203, and the surrounding portion 227C2B of the drain electrode 227C that surrounds the second overlapping portion 227C2A. The pixel electrode 228 is connected to the second overlapping portion 227C2A of the drain electrode 227C via the first pixel contact hole CH203 of the first planarization film 237. The first overlapping portion 227C1A and the surrounding portion 227C1B of the drain electrode 227C are covered by the third interlayer insulation film 236 and the second overlapping portion 227C2A and the surrounding portion 227C2B of the drain electrode 227C are not covered by the third interlayer insulation film 236. Therefore, compared to the configuration in which the entire area of the drain electrode except for the second overlapping portion is covered by the third interlayer insulation film, the area in which the third interlayer insulation film 236 is formed is reduced. As the area in which the third interlayer insulation film 236 is formed is reduced, the amount of light rays absorbed by the third interlayer insulation film 236 reduces and the amount of light rays passing through the pixel electrode 228 increases and the amount of light rays reflecting off the interface of the third interlayer insulation film 236 reduces. Accordingly, the light transmittance of the pixel electrode 228 increases.

### Other Embodiments

The technology described herein is not limited to the embodiments described above and illustrated by the drawings. For example, the following embodiments will be included in the technical scope of the present technology.
(1) The third interlayer insulation film 36, 136, 236 may be a multilayered film including a SiNₓ layer and a SiO₂ layer.
(2) The specific plan view area in which the third interlayer insulation film 36, 136, 236 is formed may be altered as appropriate from that illustrated in the drawings. For instance, as modifications of the first and third embodiments, the third interlayer insulation film 36, 136 may be formed only in an area overlapping the drain electrode 27C, 227C. Namely, the third interlayer insulation film 36, 236 may only include the first insulation portion 36A, 236A and not include the second insulation portion 36B, 236B. In the configuration of each of the first and third embodiments, the area in which the second insulation portion 36B, 236B may be larger or smaller than that described in the drawings.
(3) The pixel contact hole CH3, CH4, CH203 may be formed not to overlap the gate lines 25, 29. For instance, the pixel contact hole CH3, CH4, CH203 may be formed in a portion that is on an opposite side from the gate lines 25, 29 with respect to the drain contact hole CH2 and away from the gate lines 25, 29. Or the pixel contact hole CH3, CH4, CH203 may be formed between the drain contact hole CH2 and the gate lines 25, 29 with respect to the Y-axis direction. In any configuration, the area in which the drain electrode 27C, 127C, 227C is formed and the arrangement of the drain electrode 27C, 127C, 227C may be altered according to the arrangement of the pixel contact holes CH3, CH4, and CH203 and the area in which the third interlayer insulation film 36, 136, 236 is formed and the arrangement of the third interlayer insulation film 36, 136, and 236 may be altered.
(4) The connection portion 28A, 228A that is a portion of the second transparent electrode film may not be included. In such a configuration, the pixel electrode 28 only includes the pixel body portion 28B, which is a portion of the third transparent electrode film, and the pixel body portion 28B is directly connected to the drain electrode 27C, 127C, 227C via the first pixel contact hole CH3, CH203, and the second pixel contact hole CH4, respectively.
(5) The upper layer gate line 29 and the upper layer gate electrode 27E may not be included. In such a configuration, the third gate insulation film 33 is not included and the TFT 27 has a bottom-gate structure.
(6) The lower layer gate line 25 and the lower layer gate electrode 27A may not be included. In such a configuration, the second gate insulation film 32 is not included and the TFT 27 has a top-gate structure.
(7) The second semiconductor film may not be included. In such a configuration, the second metal film (the upper layer gate line 29 and the upper layer gate electrode 27E) and the third gate insulation film 33 are not included and the semiconductor section 27D of the TFT 27 may be a portion of the first semiconductor film and the gate electrode of the TFT 27 may be a portion of the first metal film. Thus, the TFT 27 has a top-gate structure.
(8) The first semiconductor film may not be included. In such a configuration, the first gate insulation film 31 is not included and the TFT included in the circuit 14 disposed in the non-display area NAA includes a semiconductor section that is a portion of the second semiconductor film.
(9) The semiconductor film may be made electrically conductive with a method different from that described above.
(10) A source driver may be disposed on the array substrate 21, 121 instead of the second circuit 14B.
(11) A source driver may be disposed on the flexible board 13 instead of the second circuit 14B.
(12) A gate driver may be disposed on the array substrate 21, 121 instead of the first circuit 14A.
(13) The plan view shape of the liquid crystal panel 11 may be a laterally long rectangular shape, a vertically long rectangular shape, a square, a circle, a semicircular shape, an elongated circular shape, an oval, and a trapezoid.
(14) The second semiconductor film may be an amorphous silicon thin film.
(15) The liquid crystal panel 11 may not be a transmissive type but may be a reflective type or a semi-transmissive type. With the liquid crystal panel 11 being a reflective type, the backlight 12 is not necessary.
(16) The display device may be an organic EL display device that is a self-emitting display device.
(17) Other than the head-mounted display 10HMD, a head-up display or a projector may be used as a device for magnifying images displayed on the liquid crystal panel 11 using a lens. The present technology may be applied to a display device without having a magnifying display function (such as television devices, tablet-type terminals, and smartphones).
(18) In the configuration described in (5) in which the upper layer gate line 29 and the upper layer gate electrode 27E are not included (the TFT 27 has a bottom-gate structure), the first interlayer insulation film 34 may not be formed. In such a configuration, the second interlayer insulation film 35 is included as the first insulation film in a layer upper than the semiconductor section 27D and lower than the drain electrode 27C, 127C, 227C. The drain contact hole CH2, CH202 is included in the second interlayer insulation film 35.
(19) The second interlayer insulation film 35 may not be included. In such a configuration, the first interlayer insulation film 34 is included as the first insulation film in a layer upper than the semiconductor section 27D and lower than the drain electrode 27C, 127C, 227C. The drain contact hole CH2, CH202 is included in the first interlayer insulation film 34. With the second interlayer insulation film 35 being not formed, the source line 26 and the drain electrode 27C, 127C, 227C are included in a same layer; however, the source line 26 and the drain electrode 27C, 127C, 227C do not overlap and a short circuit is not caused between the source line 26 and the drain electrode 27C, 127C, 227C that are in the same layer.

1. An array substrate comprising:
a semiconductor section made of semiconductor material;
a first insulation film disposed in a layer upper than the semiconductor section;
a first electrode that is disposed in a layer upper than the first insulation film and a portion of which overlaps a portion of the semiconductor section;
a second insulation film disposed in a layer upper than the first electrode; and
a third insulation film disposed in a layer upper than the second insulation film, wherein
the first electrode is made of transparent electrode material,
the first insulation film is made of inorganic insulation material and includes a first contact hole in a portion overlapping the semiconductor section and the first electrode and the semiconductor section and the first electrode are connected via the first contact hole,
the third insulation film is made of organic insulation material, and
the second insulation film is made of inorganic insulation material and covers at least a first overlapping portion of the first electrode that overlaps the first contact hole.

2. The array substrate according to claim 1, further comprising a pixel electrode that is disposed in a layer upper than the third insulation film and a portion of which overlaps the first electrode, wherein
the third insulation film includes a second contact hole in a portion that overlaps the first electrode and the pixel electrode and does not overlap the first contact hole, the first electrode and the pixel electrode are connected via the second contact hole, and
the second insulation film includes a third contact hole that is communicated with the second contact hole and covers an entire area of the first electrode except for a second overlapping portion of the first electrode that overlaps the second contact hole.

3. The array substrate according to claim 2, wherein the second insulation film includes a first insulation portion that overlaps the first electrode and a second insulation portion that surrounds the first insulation portion.

4. The array substrate according to claim 2, wherein
the pixel electrode includes an electrode overlapping section that overlaps the first electrode and an electrode non-overlapping section that does not overlap the first electrode, and
the second insulation film is not disposed in an area overlapping the electrode non-overlapping section.

5. The array substrate according to claim 2, wherein
the pixel electrode includes an electrode overlapping section that overlaps the first electrode and an electrode non-overlapping section that does not overlap the first electrode, and
the second insulation film is disposed in an area overlapping the electrode non-overlapping section.

6. The array substrate according to claim 1, further comprising a pixel electrode that is disposed in a layer upper than the third insulation film and a portion of which overlaps the first electrode, wherein
the third insulation film includes a second contact hole in a portion that overlaps the first electrode and the pixel electrode and does not overlap the first contact hole, the first electrode and the pixel electrode are connected via the second contact hole,
the second insulation film is disposed in an area that overlaps the first overlapping portion and a surrounding portion of the first electrode that surrounds the first overlapping portion, and
the second insulation film is not disposed in an area that overlaps a second overlapping portion of the first electrode that overlaps the second contact hole and an area that overlaps a surrounding portion of the first electrode that surrounds the second overlapping portion.

7. The array substrate according to claim 1, further comprising:
a pixel electrode that is disposed in a layer upper than the third insulation film and a portion of which overlaps the first electrode; and
a first line made of conductive material having light blocking properties and disposed in a layer lower than the first insulation film, wherein
the third insulation film includes a second contact hole in a portion that overlaps the first electrode and the pixel electrode and the first line, the first electrode and the pixel electrode are connected via the second contact hole.

8. The array substrate according to claim 1, wherein the second insulation portion includes silicon nitride as the inorganic insulation material.

9. The array substrate according to claim 1, further comprising:
a fourth insulation film disposed in a layer lower than the semiconductor section;
a second electrode disposed in a layer lower than the fourth insulation film and disposed to overlap a portion of the semiconductor section; and
a third electrode disposed not to overlap the first electrode and the second electrode and connected to the semiconductor section, wherein
the first electrode, the second electrode, the third electrode, and the semiconductor section are configured as a transistor.

10. The array substrate according to claim 1, further comprising:
a fifth insulation film disposed in a layer upper than the semiconductor section and lower than the first insulation film;
a fourth electrode disposed in a layer upper than the fifth insulation film and lower than the first insulation film and disposed to overlap a portion of the semiconductor section; and
a third electrode disposed not to overlap the first electrode and the fourth electrode and connected to the semiconductor section, wherein
the first electrode, the fourth electrode, the third electrode, and the semiconductor section are configured as a transistor.

11. A display device comprising:
the array substrate according to claim 1; and
an opposed substrate disposed to opposite the array substrate.
